(19) United States
(12) Patent Application Publication
(10) Pub. No.: US 2011/0175184 A1
(43) Pub. Date: Jul. 21, 2011

(54) SOLID-STATE IMAGING DEVICE AND METHOD OF MANUFACTURING SOLID-STATE IMAGING DEVICE

(75) Inventor: Kazufumi SUGAWARA, Saitama-shi (JP)

(73) Assignee: FUJIFILM CORPORATION, Tokyo (JP)

(21) Appl. No.: 12/979,276

(22) Filed: Dec. 27, 2010

(30) Foreign Application Priority Data
Jan. 21, 2010 (JP) P2010-011371

(51) Int. Cl. H01L 31/0216; H01L 31/18

(52) U.S. Cl. 257/432; 438/65; 257/E31.122; 257/E31.001

(57) ABSTRACT

The invention provides a solid-state imaging device and a method of manufacturing a solid-state imaging device capable of reducing a variation in the shape of an in-layer lens and deeply forming a lens portion. Disclosed is a method of manufacturing a solid-state imaging device including a photoelectric conversion unit and a light shielding film. The method includes: forming the light shielding film; forming a first insulating film and performing a reflow process on the first insulating film; etching the first insulating film such that the first insulating film remains only in a side portion of the light shielding film; forming a second insulating film; and forming another insulating film. A lens portion is formed on another insulating film so as to protrude toward the photoelectric conversion unit, and the lens portion has a shape corresponding to the surface shape of the second insulating film.

### BACKGROUND OF THE INVENTION

1. Field of the Invention

The present invention relates to a solid-state imaging device and a method of manufacturing a solid-state imaging device.

2. Description of the Related Art

Imaging apparatuses, such as digital camera, include CCD-type or CMOS-type solid-state imaging devices. The solid-state imaging device is manufactured by forming a photoelectric conversion unit that generates charge according to incident light, a charge transfer electrode that transfers the charge to the output side, and an interlayer insulating film on a semiconductor substrate in a predetermined order.

In the solid-state imaging device, a pseudo-signal is generated due to charge generated from a region other than the photoelectric conversion unit, that is, so-called smear occurs, which causes the deterioration of image quality. In particular, in the latest solid-state imaging device, when the number of pixel units increases in order to capture a high-quality image, the structure of a photoelectric conversion element forming the pixel unit or a peripheral circuit is miniaturized. Therefore, smear is more likely to occur.

In order to prevent the occurrence of the smear, a technique has been proposed which uses an in-layer lens structure, reduces the distance between a lens portion and a photoelectric conversion unit (deeply forms the lens portion), and makes converging light incident on the photoelectric conversion unit. FIGS. 5A to 5C show a process of forming the in-layer lens in a method of manufacturing a solid-state imaging device.

As shown in FIG. 5A, first, an embedded photodiode 102 is formed on the surface of a semiconductor substrate 101, and an insulating film 104, a transfer electrode 106, and a light shielding film 108 covering the transfer electrode 106 are formed on the semiconductor substrate 101.

Then, as shown in FIG. 5B, an interlayer insulating film (BPSG: Boron Phosphor Silicate Glass) 122 is formed on the entire surface of the semiconductor substrate 101, and a reflow process is performed. In this case, the interlayer insulating film 122 is melted by the reflow process and the surface of the interlayer insulating film 122 is smoothed. Then, as shown in FIG. 5C, a nitride film (P—SiN) 126 is formed on the interlayer insulating film 122 by plasma CVD (Chemical Vapor Deposition). A lens portion 126a serving as an in-layer lens having a convex shape with a protruding portion facing downward is formed so as to correspond to the surface shape of the interlayer insulating film 122. In the related art, JP2003-249634A, JP1999-103037A and JP2007-214374A disclose a method of manufacturing the solid-state imaging device including the interlayer insulating film 122.

### SUMMARY OF THE INVENTION

However, in the manufacturing process according to the related art, it is possible to reduce the occurrence of smear a little, but the controllability of the shape of the lens portion 126a is not sufficient and there is a variation in the shape of the lens portion 126a in each pixel unit. Therefore, the manufacturing process according to the related art needs to be improved. In addition, it is difficult to accurately position the lens portion 126a due to the variation in the shape. When there is a large variation in the shape or position of the lens, incident light is dispersed. As a result, smear is likely to occur.

In addition, in the manufacturing process according to the related art, in order to reduce the occurrence of smear, a technique has been proposed which performs the reflow process on the interlayer insulating film 122, etches the interlayer insulating film 122 to remove a portion thereof, and performs the reflow process again to deeply form the lens portion 126a. In this method, the controllability of the shape of the lens portion 126a is also reduced.

The invention has been made in view of the above-mentioned problems and an object of the invention is to provide a solid-state imaging device and a method of manufacturing a solid-state imaging device capable of reducing the occurrence of smear and deeply forming a lens portion while reducing variation in the shape of in-layer lenses.

In order to achieve the object, according to an aspect of the invention, there is provided a method of manufacturing a solid-state imaging device including a photoelectric conversion unit that is provided on a semiconductor substrate and generates a signal charge according to incident light and a light shielding film having an opening provided above the photoelectric conversion unit. The method includes: forming the light shielding film; forming a first insulating film including a single layer or a plurality of layers on the light shielding film so as to cover the opening and the light shielding film and performing a reflow process on the first insulating film; etching the first insulating film such that the first insulating film remains only in a side portion of the light shielding film; forming a second insulating film which is the same kind as the first insulating film on the photoelectric conversion unit after the etching; and forming another insulating film with a refractive index different from that of the second insulating film on the second insulating film. A lens portion is formed on the another insulating film on the second insulating film so as to protrude toward the photoelectric conversion unit, and the lens portion has a shape corresponding to the surface shape of the second insulating film. The term “component on or above” means a component separated from the photoelectric conversion unit to the lens. The term “side portion” means a portion of the inner wall of the opening of the light shielding portion close to the photoelectric conversion unit. The term “same kind of insulating film” means an insulating film with a refractive index difference of 10% or less from the first insulating films, regardless of a material forming the insulating film. The term “another insulating film with a different refractive index” means an insulating film with a refractive index that is more than 10% of that of the second insulating film, regardless of a material forming the insulating film.

In the method of manufacturing a solid-state imaging device according to the above-mentioned aspect, the first insulating film may include a BPSG film, or an oxide film and the BPSG film.

In the method of manufacturing a solid-state imaging device according to the above-mentioned aspect, the second insulating film may be an oxide film that is formed by CVD using TEOS or plasma CVD using monosilane.

In the method of manufacturing a solid-state imaging device according to the above-mentioned aspect, the first insulating film and the second insulating film may be oxide films.

In the method of manufacturing a solid-state imaging device according to the above-mentioned aspect, the insulating film on the second insulating film may be a nitride film. A nitride film may be formed as a base on the semiconductor substrate in advance. When the first insulating film is etched, the etching may stop with the nitride film.

According to another aspect of the invention, a solid-state imaging device includes: a photoelectric conversion unit that is provided on a semiconductor substrate and generates a signal charge according to incident light; a light shielding film that covers a transfer electrode and has an opening provided above the photoelectric conversion unit; a side wall that is a first insulating film including a single layer or a plurality of layers and is provided in a side portion of the light shielding film; a second insulating film that covers the side wall and the light shielding film; and another insulating film that is provided so as to cover the opening and the light shielding film and has a refractive index different from that of the second insulating film. Another insulating film on the second insulating film has a lens portion protruding toward the photoelectric conversion unit, and the lens portion has a shape corresponding to the surface shape of the second insulating film.

It is preferable that the first insulating film remaining only in the side portions of the pixel peripheral portions provided on both sides of the pixel unit be a SOG film, a BPSG film, or a combination of the BSPG film or the SOG film and an oxide film. According to the invention, the first insulating film is etched so as to remain only in the side portion (a portion of the inner wall of the opening of the light shielding film close to the pixel unit) of the light shielding film. In this way, the side wall, which is the first insulating film, is formed. The side wall regulates a portion of the shape of the in-layer lens. The second insulating film is formed on the portion in which the first insulating film is removed. The second insulating film has a shape tracing the lens shape together with the side wall, which is the first insulating film.

According to the invention, in a solid-state imaging device including an in-layer lens, it is possible to deeply form a lens portion while reducing a variation in the shape of the lens portion.

### BRIEF DESCRIPTION OF THE DRAWINGS

FIG. 1 is a diagram schematically illustrating the structure of a solid-state imaging device.

FIG. 2 is a plan view illustrating an example of the structure of the solid-state imaging device shown in FIG. 1.

FIG. 3 is a cross-sectional view illustrating the solid-state imaging device shown in FIG. 2, as viewed from an arrow direction.

FIGS. 4A to 4E are cross-sectional views schematically illustrating the procedure of a method of manufacturing the solid-state imaging device.

FIGS. 5A to 5C are diagrams illustrating the procedure of a method of manufacturing a solid-state imaging device according to the related art.

### DESCRIPTION OF THE PREFERRED EMBODIMENTS

Hereinafter, exemplary embodiments of the invention will be described in detail with reference to the accompanying drawings.

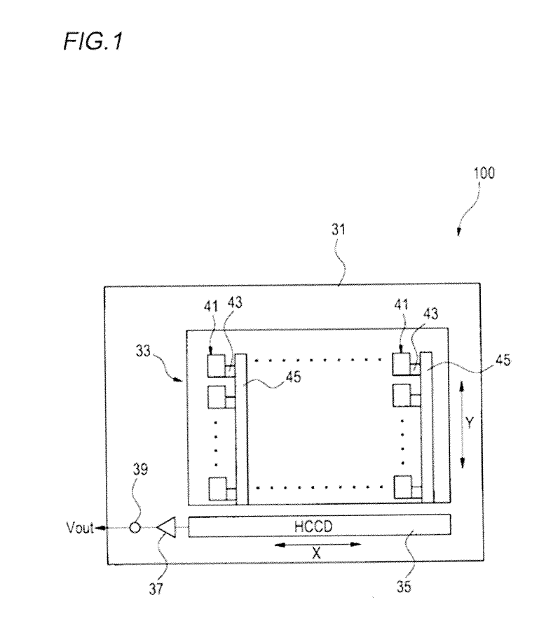

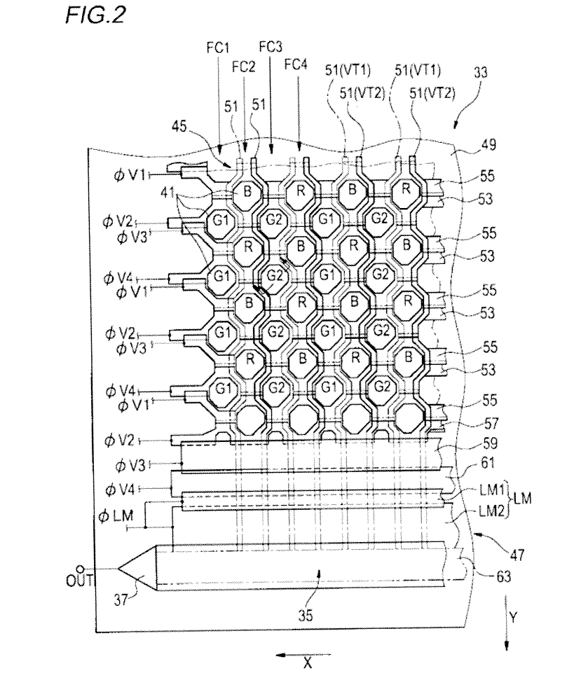

FIG. 1 is a diagram schematically illustrating the structure of a solid-state imaging device. FIG. 2 is a plan view illustrating an example of the structure of the solid-state imaging device shown in FIG. 1.

As shown in FIG. 1, a solid-state imaging device 100 includes a light receiving region 33, a horizontal charge transfer unit (HCCD) 35, an amplifier 37, and a signal output terminal 39 provided in an imaging device forming region 31. Photoelectric conversion units 41, charge reading units 43, and vertical charge transfer units 45 are provided in the light receiving region 33.

As shown in FIG. 2, the solid-state imaging device 100 includes the light receiving region 33 in which a plurality of photoelectric conversion units 41 is two-dimensionally arranged in the row direction (the direction of an arrow X) and the column direction (the direction of an arrow Y) in a plan view. Each of the photoelectric conversion units 41 includes a photodiode (PD) made of a semiconductor.

A plurality of vertical charge transfer units 45, a line memory 47, and the horizontal charge transfer unit 35 are provided in order to extract a signal charge output from each of the plurality of photoelectric conversion units 41, which is two-dimensionally arranged, as a signal for each of the time-series frames output from the output terminal of the solid-state imaging device.

A signal charge corresponding to one row which is stored in the line memory 47 is transferred from the line memory 47 to the horizontal charge transfer unit 35. As a result, the signal charge corresponding to one row is input to the horizontal charge transfer unit 35. The horizontal charge transfer unit 35 sequentially transfers the signal charge corresponding to one row, which is stored therein, for each pixel in the horizontal direction (the direction of the arrow X). The signal charge transferred from the horizontal charge transfer unit 35 is converted into a voltage and is then output from an output terminal OUT.

A timing signal generating circuit (not shown) generates control signals required to perform the above-mentioned reading operation, that is, a vertical transfer control signal φV (generally, signals with a plurality of phases), a transfer control signal φLM, and a horizontal transfer control signal φH (generally, signals with a plurality of phases), and the generated control signals are applied to each of the vertical charge transfer units 45, the line memory 47, and the horizontal charge transfer unit 35 of the solid-state imaging device. The line memory 47 may be omitted.

As shown in FIG. 2, the solid-state imaging device 100 is arranged such that the plurality of photoelectric conversion units 41 forms a honeycomb pattern (a pattern in which the arrangement positions of the photoelectric conversion units deviate from each other at a half pitch in the horizontal direction). In FIG. 2, as represented by “G1”, “G2”, “B”, and “R”, color components detected by each of the photoelectric conversion units 41 are predetermined. That is, the photoelectric conversion units 41 represented by “G1” and “G2” detect a green light component, the photoelectric conversion units 41 represented by “B” detect a blue light component, and the photoelectric conversion units 41 represented by “R” detect a red light component.

The colors to be detected are set by the spectral characteristics of an optical filter provided in front of a light receiving surface of each photoelectric conversion unit 41. In the example shown in FIG. 2, four kinds of filter columns FC1, FC2, FC3, and FC4 for each column of photoelectric conversion units 41 are arranged. The optical filters are arranged in an array that is inclined at an angle of 45° with respect to a so-called Bayer array. However, the arrangement of the optical filters is not particularly limited.

The vertical charge transfer units 45 are arranged in an S shape at positions adjacent to each column of photoelectric conversion units 41. Each of the vertical charge transfer units 45 includes a vertical charge transfer channel 51 which is provided on a semiconductor substrate 49 and a plurality of first vertical transfer electrodes 53, second vertical transfer electrodes 55, first auxiliary transfer electrodes 57, second auxiliary transfer electrodes 59, and third auxiliary transfer electrodes 61 for charge transfer, which are provided on the semiconductor substrate 49 with an electrical insulating film (not shown) interposed therebetween. The horizontal charge transfer unit 35 includes a horizontal charge transfer channel 63 that extends in a strip shape in the direction of the arrow X.

That is, it is possible to sequentially transfer the signal charge of each pixel from the vertical charge transfer unit (VCCD) 45 in a desired direction by applying a predetermined voltage to each of the electrodes 53, 55, 57, 59, and 61 to form a predetermined potential distribution on each vertical charge transfer channel 51 and sequentially switching the voltage applied to each electrode.

One first vertical transfer electrode 53 and one second vertical transfer electrode 55 are formed for each row of photoelectric conversion units 41. Each first vertical transfer electrode 53 also functions as a read gate for controlling the transfer of the signal charge from the photoelectric conversion unit 41 to the vertical charge transfer channel 51 of the vertical charge transfer unit 45.

As shown in FIG. 2, any one of four-phase vertical transfer control signals (also referred to as driving pulses) φV1, φV2, φV3, and φV4 is applied to each of the second vertical transfer electrodes 55 and the first vertical transfer electrodes 53 which are alternately arranged in the direction of the arrow Y according to the positional relationship between the second vertical transfer electrodes 55 and the first vertical transfer electrodes 53. Similarly, the vertical transfer control signal φV2 is applied to the first auxiliary transfer electrode 57, the vertical transfer control signal φV3 is applied to the second auxiliary transfer electrode 59, and the vertical transfer control signal φV4 is applied to the third auxiliary transfer electrode 61. In addition, the transfer control signal φLM is applied to the transfer control electrodes LM1 and LM2 in order to control the transfer of the signal charge in the line memory 47.

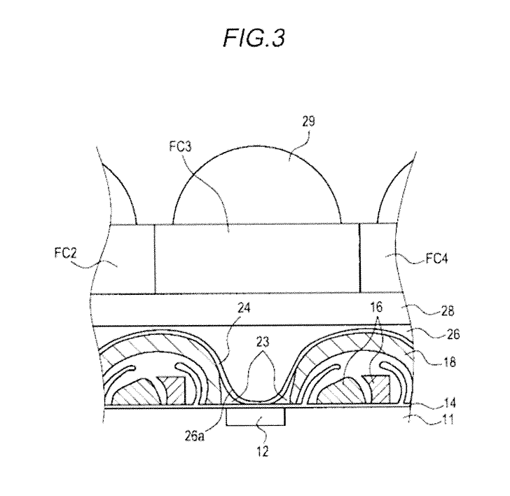

FIG. 3 is a cross-sectional view as viewed from the arrow direction of FIG. 2.

In the cross-sectional view of one photoelectric conversion unit 41 of the solid-state imaging device 100, an embedded photodiode 12 is formed on the semiconductor substrate 11. A thin P-type region may be formed on the surface of the photodiode 12. In addition, for example, a charge transfer channel (not shown) is formed in the semiconductor substrate 11 by an impurity diffusion region.

A gate insulating film 14 is formed on the surface of the semiconductor substrate 11. The gate insulating film 14 may have, for example, a laminated structure in which a silicon nitride (SiN) film with high voltage resistance is interposed between silicon oxide (SiO) films, that is, a so-called ONO film structure.

A transfer electrode 16 is formed on the gate insulating film 14 of the semiconductor substrate 11. The transfer electrode 16 is made of polysilicon or silicide. A light shielding film 18 is formed on the transfer electrode 16 so as to cover an upper part of the transfer electrode 16. The light shielding film 18 has an opening that is provided above the photodiode 12.

The transfer electrode 16 and the light shielding film 18 are included in a pixel peripheral portion. The pixel peripheral portion is provided above a region other than the region of the photodiode 12 formed on the surface of the semiconductor substrate 11. A film or layer forming the pixel peripheral portion is not particularly limited.

The gate insulating film on the photodiode 12 is formed in an ONO film structure, similar to other portions, and then the upper oxide film and the nitride film of the gate insulating film are removed. Then, another nitride film is formed on the gate insulating film. In the pixel peripheral portion, the nitride film forms an anti-reflection film that is formed so as to cover the transfer electrode 16. In addition, the nitride film also functions as an etching stopper, which will be described below.

A side wall 23 is provided only in a side portion of the light shielding film 18. The side wall 23 is an insulating film (referred to as a first insulating film). The insulating film is a single BPSG film or a single SOG film, or a plurality of oxide films and BPSG films or SOG films. The side wall 23 is formed so as to extend from the vicinity of an upper part of the light shielding film 18 to the upper side of the photodiode 12 while covering the corners of the light shielding film 18 and a base film of the light shielding film 18, that is, an anti-reflection film. A process of forming the oxide film, the BPSG film, or the side wall 23 including the films will be described below.

An oxide film 24 is provided so as to cover the light shielding film 18 and the side wall 23. The oxide film 24 is a second insulating film. In this example, the oxide film 24 is the same kind as the first insulating film that is provided below the oxide film 24 in advance since the first insulating film is an oxide film. However, the oxide film 24 may be the same kind of insulating film as a base, but is not limited to the oxide film. The “same kind of films” means the films that are represented by the same chemical formula and have substantially the same refractive index and transmittance (for example, within ±5%).

A nitride film 26 is formed on the oxide film 24. The nitride film 26 includes a lens portion 26a that is disposed in the opening of the light shielding film 18 and protrudes toward the upper part of the photodiode 12. The lens portion 26a functions as an in-layer lens. The lens portion 26a has a surface shape (that is, a lens shape) corresponding to the surface shape of the side wall 23 formed in the side portion of the light shielding film 18. The nitride film 26 provided on the oxide film 24 may be another insulating film. The refractive index of another insulating film is different from that of the oxide film 24.

A planarizing layer 28 is formed on the nitride film 26 and an optical filter is formed on the planarizing layer 28. A convex micro-lens 29 with a protruding portion facing upward is formed on the optical filter in each pixel unit.

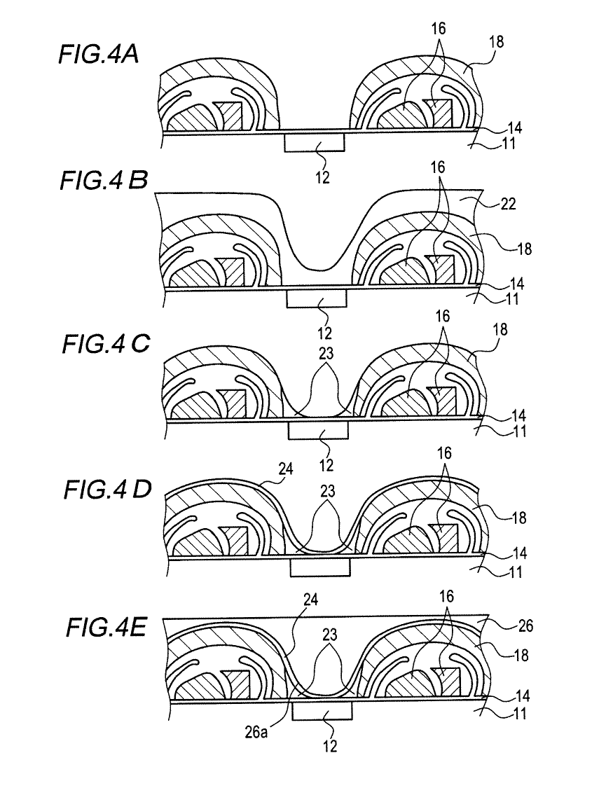

FIGS. 4A to 4E are diagrams illustrating a process of forming the in-layer lens when the solid-state imaging device is manufactured. FIGS. 4A to 4E show one photoelectric conversion unit 41 and the pixel peripheral portions adjacent to both sides of the photoelectric conversion unit 41.

As shown in FIG. 4A, the photodiode 12 and other impurity diffusion regions are formed on the semiconductor substrate 11 and then the gate insulating film 14 is formed on the surface of the semiconductor substrate 11. The gate insulating film 14 of the photodiode 12 is formed in the ONO film structure at the same time as the gate insulating film 14 in another region is formed. Then, the upper oxide film and the nitride film (not shown) in the ONO film structure are removed and then another nitride film is formed. When the nitride film is formed, the anti-reflection film, which is the nitride film, is formed in the pixel peripheral portion. In the pixel peripheral portion, after the gate insulating film is formed, the transfer electrode 16, the anti-reflection film, and the light shielding film 18 are formed on the gate insulating film 14. The same process as that in a known manufacturing method may be appropriately used to form the gate insulating film 14, the transfer electrode 16, or the light shielding film 18. However, in the invention, the process is not particularly limited.

As shown in FIG. 4B, an oxide film (for example, a monosilane-based plasma oxide film) and a BPSG film 22 are formed in this order by CVD so as to cover the light shielding films 18 and the region between the light shielding films 18 through which the gate insulating film is exposed.

After the oxide film and the BPSG film 22 are formed, a reflow process is performed. The BPSG film 22 is melted by heat in the reflow process and a portion of the molten BPSG film 22 flows to an upper part of the pixel unit, that is, a concave portion between the pixel peripheral portions. Therefore, the thickness of the BPSG film 22 above the photodiode 12 is greater than that of the BPSG film 22 on the light shielding film 18.

After the reflow process, the BPSG film 22 in the light receiving region is etched. Etching is performed as shown in FIG. 4C to form the side wall 23 only in the side portion of the pixel peripheral portion. As the etching, isotropic etching or anisotropic etching may be used. When isotropic etching is performed, the shape of the lens portion to be formed in the subsequent process can trace the shape when the reflow process is performed on the oxide film. When anisotropic etching is performed, the BPSG film 22 can be etched in the depth direction of the lens portion. Regions other than the pixel region including the pixel units and the pixel peripheral portions are covered with a resist. The side wall 23 is formed by the oxide film remaining after etching, or the oxide film and the BPSG film 22.

The surface of the light shielding film 18 other than the side portion (the portion where the side wall 23 is formed) is exposed by etching. When etching is performed, the nitride film can be used as an etching stopper by the selectivity of the nitride film and the oxide film which are formed as a base on the photodiode 12 in advance. As a method other than the method of using the nitride film as the etching stopper, the time required to perform a predetermined amount of etching may be experimentally calculated in advance, and etching may be performed for this time and stop after the time has elapsed.

After the etching is performed, as shown in FIG. 4D, the oxide film 24 is formed so as to cover all of the light shielding film 18, the side portion of the light shielding film 18, and the pixel unit by plasma CVD using tetraethoxy silane (TEOS) as a raw material gas. The oxide film 24 and the oxide film formed before the BPSG film 22 are the same kind of films. The oxide film 24 is advantageous in that it is formed with a thickness smaller than that of the BPSG film. The oxide film 24 may be formed by plasma CVD using a monosilane-based compound.

After the oxide film 24 is formed, as shown in FIG. 4E, the nitride film 26, which is a filling material, is formed on the oxide film 24 and the nitride film 26 is planarized by resist etch back. As shown in FIG. 3, the optical filter and the micro-lens 29 are formed on the nitride film 26.

A portion of the nitride film 26 flows into a concave portion between the pixel peripheral portions above the pixel unit, and the lens portion 26a corresponding to the surface shape of the side portion of the pixel peripheral portion is formed. The lens portion 26a has a lens effect obtained by the difference between the refractive indexes of the oxide film 24 and the nitride film 26.

According to this process, it is possible to deeply form the lens portion 26a to the lower side (pixel unit side) by etching the base film above the pixel unit. During etching, the side wall 23 remains in the side portion of the light shielding film 18 in the pixel peripheral portion. Therefore, it is possible to form the lens portion 26a with a uniform depth between the pixel units while ensuring the lens shape of the lens portion 26a to be formed in the subsequent process.

The oxide film 24 formed on the pixel unit is disposed below a part of the convex lens portion 26a that protrudes downward, and the thickness of the film is controlled by etching. When reflow and etching are performed on the oxide film below the in-layer lens, it is difficult to control the oxide film to a predetermined thickness. According to the above-mentioned process, the oxide film that comes into contact with the surface of the lens portion 26 is provided by only a film deposition process, and it is possible to form the oxide film 24 with a desired thickness. In addition, it is possible to determine the thickness (the thickness of a portion protruding downward) of the lens portion 26a using a single deposition process.

In the solid-state imaging device manufactured by the above-mentioned process, the side wall 23 including the first insulating film, or the first insulating film and the BPSG film 22 is formed only in the side portion of the pixel peripheral portion. That is, the BPSG film 22 is not formed on the pixel peripheral portion, unlike the related art. Therefore, it is possible to reduce the overall thickness of the solid-state imaging device.

In the above-mentioned example, the structure of the CCD-type solid-state imaging device is given as an example. However, the invention can be applied to a CMOS-type solid-state imaging device. In the case of the CCD-type solid-state imaging device, the in-layer lens is provided in the opening to reduce smear.

### Examples

An imaging element (prior art example) manufactured by a manufacturing method according to the related art and an imaging device (example) manufactured by a manufacturing method according to the invention were prepared as samples and were evaluated, as follows.

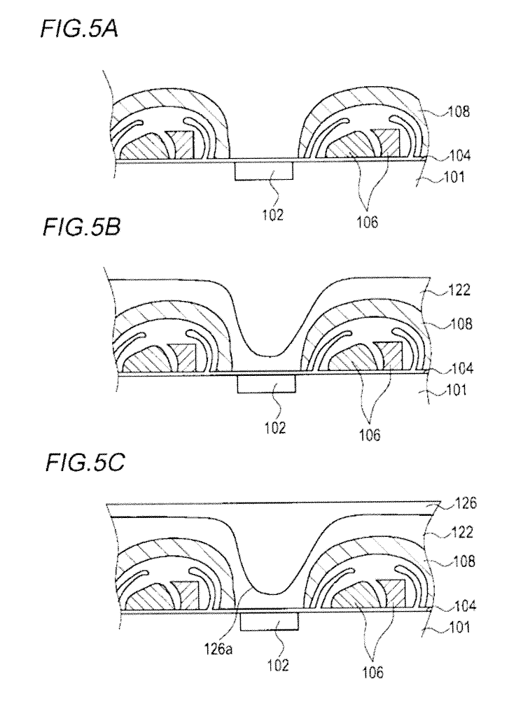

In a process of manufacturing the imaging device according to the prior art example, first, an embedded photodiode was formed on the surface of a semiconductor substrate, and an insulating film, a transfer electrode, and a light shielding film covering the transfer electrode were formed on the semiconductor substrate (see FIG. 5A). Then, a BPSG film was formed on the entire surface of the semiconductor substrate and a reflow process was performed (see FIG. 5B). Then, a nitride film was formed on the BPSG film by plasma CVD. Then, a lens portion corresponding to the surface shape of the BPSG film was formed. In this way, the imaging device was obtained (see FIG. 5C).

In a process of manufacturing an imaging device according to the example, first, an embedded photodiode was formed on the surface of a semiconductor substrate and an insulating film, a transfer electrode, and a light shielding film covering the transfer electrode were formed on the semiconductor substrate (see FIG. 4A). Then, a BPSG film was formed on the entire surface of the semiconductor substrate and a reflow process was performed (see FIG. 4B). Then, the BPSG film 22 in the light receiving region was etched (see FIG. 4C). Then, an oxide film was formed by plasma CVD using TEOS so as to cover the light shielding film, a side portion of the light shielding film, and an upper part of the pixel unit (see FIG. 4D). Then, a nitride film, which is a filling material, is formed on the oxide film, and the nitride film was planarized by resist etch back. A lens portion is formed on the nitride film. In this way, the imaging device according to the example was obtained (see FIG. 4E).

The quality of the imaging devices was evaluated as follows: the distance between the in-layer lens and the photodiode of nine imaging devices according to each of the prior art example and the example was measured and the degree of deviation of the measured distance from a predetermined value was calculated. As a result, in the imaging device according to the prior art example, the deviation of the measured distance from a predetermined value was within ±40%. However, in the imaging device according to the example, the deviation of the measured distance from a predetermined value was within ±5%. The result proved that a variation in the shape of the imaging device according to the example was smaller than that of the imaging device according to the prior art example and the quality of the imaging device according to the example was higher than that of the imaging device according to the prior art example. In addition, the frequency of occurrence of smear in the imaging device according to the example was less than that in the imaging device according to the prior art example.

1. A method of manufacturing a solid-state imaging device including a photoelectric conversion unit that is provided on a semiconductor substrate and generates a signal charge according to incident light and a light shielding film having an opening provided above the photoelectric conversion unit, comprising:
forming the light shielding film;
forming a first insulating film including a single layer or a plurality of layers on the light shielding film so as to cover the opening and the light shielding film and performing a reflow process on the first insulating film;
etching the first insulating film such that the first insulating film remains only in a side portion of the light shielding film;
forming a second insulating film which is the same kind as the first insulating film on the photoelectric conversion unit after the etching; and
forming another insulating film with a refractive index different from that of the second insulating film on the second insulating film,
wherein a lens portion is formed on the another insulating film on the second insulating film so as to protrude toward the photoelectric conversion unit, and
the lens portion has a shape corresponding to the surface shape of the second insulating film.

2. The method of manufacturing a solid-state imaging device according to claim 1,
wherein the first insulating film consists of a BPSG film, or an oxide film and the BPSG film.

3. The method of manufacturing a solid-state imaging device according to claim 1,
wherein the second insulating film comprises an oxide film that is formed by CVD using TEOS or plasma CVD using monosilane.

4. The method of manufacturing a solid-state imaging device according to claim 1,
wherein the first insulating film and the second insulating film comprise oxide films.

5. The method of manufacturing a solid-state imaging device according to claim 1,
wherein the insulating film on the second insulating film comprises a nitride film,
a nitride film is formed as a base on the semiconductor substrate in advance, and
when the first insulating film is etched, the etching stops with the nitride film.

6. A solid-state imaging device comprising:
a photoelectric conversion unit that is provided on a semiconductor substrate and generates a signal charge according to incident light;
a light shielding film that covers a transfer electrode and has an opening provided above the photoelectric conversion unit;
a side wall that is a first insulating film including a single layer or a plurality of layers and is provided in a side portion of the light shielding film;
a second insulating film that covers the side wall and the light shielding film; and
another insulating film that is provided so as to cover the opening and the light shielding film and has a refractive index different from that of the second insulating film,
wherein the another insulating film on the second insulating film has a lens portion protruding toward the photoelectric conversion unit, and
the lens portion has a shape corresponding to the surface shape of the second insulating film.

7. The method of manufacturing a solid-state imaging device according to claim 2,
wherein the second insulating film comprises an oxide film that is formed by CVD using TEOS or plasma CVD using monosilane.

8. The method of manufacturing a solid-state imaging device according to claim 2,
wherein the first insulating film and the second insulating film comprise oxide films.

9. The method of manufacturing a solid-state imaging device according to claim 2,
wherein the insulating film on the second insulating film comprises a nitride film,
a nitride film is formed as a base on the semiconductor substrate in advance, and
when the first insulating film is etched, the etching stops with the nitride film.

10. The method of manufacturing a solid-state imaging device according to claim 1,
wherein the first insulating film comprises a BPSG film, or an oxide film and the BPSG film.
